(19) United States
(12) Patent Application Publication
(10) Pub. No.: US 2016/0343738 A1
(43) Pub. Date: Nov. 24, 2016

(54) THIN FILM TRANSISTOR OF ARRAY SUBSTRATE AND MANUFACTURING METHOD THEREOF

(71) Applicant: HON HAI PRECISION INDUSTRY CO., LTD., New Taipei (TW)

(72) Inventors: YI-CHUN KAO, New Taipei (TW); HSIN-HUA LIN, New Taipei (TW); CHIH-LUNG LEE, New Taipei (TW); KUO-LUNG FANG, New Taipei (TW); PO-LI SHIH, New Taipei (TW)

(21) Appl. No.: 14/833,658

(22) Filed: Aug. 24, 2015

(30) Foreign Application Priority Data
May 21, 2015 (TW) 104116346

(51) Int. Cl. H01L 27/12; H01L 21/027; H01L 29/66; H01L 29/786; H01L 29/423

(52) U.S. Cl. CPC H01L 27/1225; H01L 29/7869; H01L 29/42384; H01L 29/66969; H01L 27/1288; H01L 21/0274; H01L 29/78606

(57) ABSTRACT

A method for manufacturing a thin film transistor (TFT), the TFT includes a gate, a first insulation layer, a channel layer, a source, a drain, a second insulation, and a flat layer. The gate is formed on a base. The first insulation layer is formed on the base to cover the gate and the base. The channel layer is formed on the first insulation layer corresponding to the gate. The second insulation layer is formed on the base to cover the first insulation layer, the channel layer, the source, and the drain. The flat layer includes a first region and a second region and is formed on the second insulation layer. The first region and the second region respectively have different light transmittance.

### CROSS-REFERENCE TO RELATED APPLICATIONS

This application claims priority to Taiwanese Patent Application No. 104116578 filed on May 22, 2015, the contents of which are incorporated by reference herein.

### FIELD

The subject matter herein generally relates to a thin film transistor (TFT) formed on an array substrate of a liquid crystal display (LCD) devices and a manufacturing method of the TFT.

### BACKGROUND

Liquid crystal display (LCD) devices are widely used, because their small size, light weight, low radiation, low power cost, and full-color display. Generally, an LCD panel can include a pair of substrates (such as an array substrate and an opposite substrate opposite to the array substrate) and a liquid crystal layer sandwiched between the pair of substrates. Generally, a flat layer or an insulation layer may be formed on a side of the array substrate adjacent to the liquid crystal layer.

### BRIEF DESCRIPTION OF THE DRAWINGS

Implementations of the present technology will now be described, by way of example only, with reference to the attached figures.

FIG. 1 illustrates a diagrammatic view of a display panel having a pair of substrates and a liquid crystal layer sandwiched between the pair of substrates.

FIG. 2 illustrates a diagrammatic partial view of a first substrate of the display panel of FIG. 1.

FIG. 3 illustrates a cross sectional view of the first substrate taken along line III-III of FIG. 2.

FIG. 4 illustrates a flowchart of method for manufacturing a TFT of FIG. 3.

FIG. 5 illustrates a diagrammatic view of a gate formed on a base in the method for manufacturing the TFT of FIG. 3.

FIG. 6 illustrates a diagrammatic view of a first insulation layer is formed on the base to cover the gate and a channel layer is formed on the first insulation layer.

FIG. 7 illustrates a diagrammatic view of the a source and a drain are respectively formed to couple with opposite sides of the channel layer.

FIG. 8 illustrates a diagrammatic view of a second insulation layer and a flat layer are respectively formed on the base in that order.

FIG. 9 illustrates a diagrammatic view of a photomask is used to expose the flat layer from a side of the flat layer away from the base.

FIG. 10 illustrates a diagrammatic view of the flat layer is exposed by the UV light from a side of the base away from the flat layer without using the photomask.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “coupled” is defined as connected, whether directly or indirectly through intervening components, and is not necessarily limited to physical connections. The connection can be such that the objects are permanently connected or releasably connected. The term “comprising”, when utilized, means “including, but not necessarily limited to”; it specifically indicates open-ended inclusion or membership in the so-described combination, group, series and the like.

The present disclosure is described in relation to an array substrate that can be used in a liquid crustal display device and a manufacturing method of the array substrate.

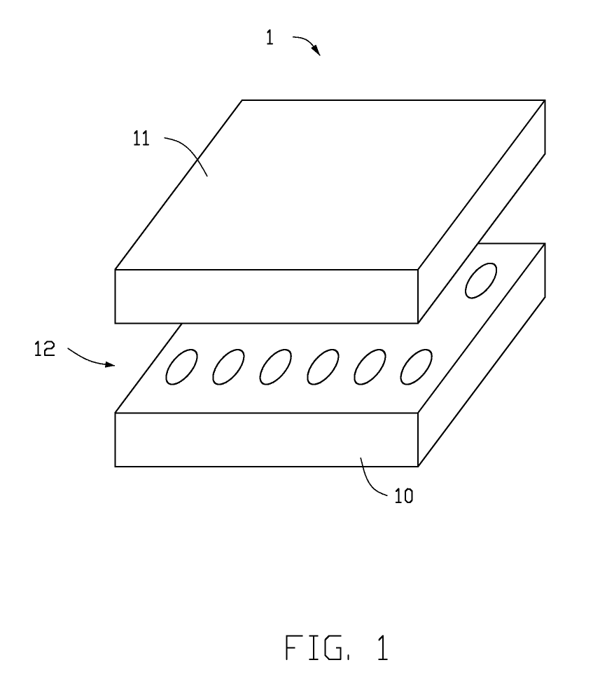

FIG. 1 illustrates a display panel 1 that includes a pair of substrates consisting of a first substrate 10 and a second substrate 11 and a liquid crystal layer 12 sandwiched between the first substrate 10 and the second substrate 11. In at least one embodiment, the display panel can be an LCD panel. The first substrate 10 can be an array substrate of the LCD panel. The second substrate 12 can be a color filter substrate of the LCD panel. Since the second substrate 11 is located opposite to the array substrate, the second substrate 12 can be also called an opposite substrate. In other embodiments, the first substrate 11 includes a plurality of TFTs located thereon. Therefore, the first substrate 11 can be also called a TFT substrate.

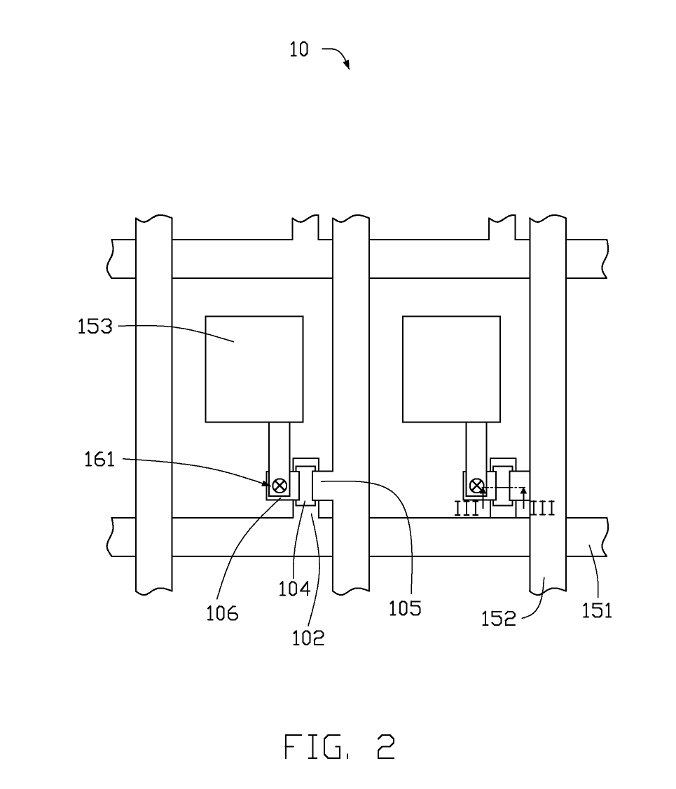

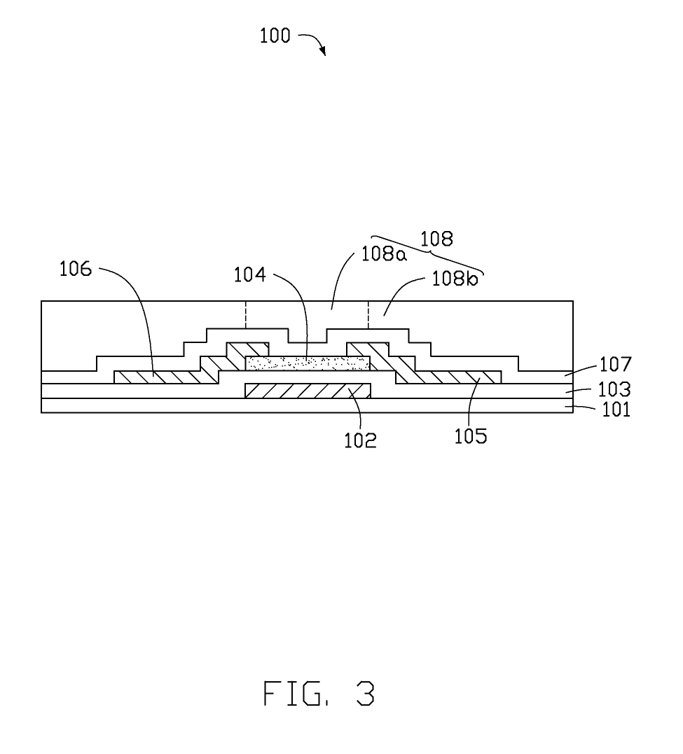

FIG. 2 illustrates a diagrammatic partial view of the first substrate 10 of the display panel 1 of FIG. 1. FIG. 3 illustrates a cross sectional view of the first substrate 10 taken along line III-III of FIG. 2. In the illustrated embodiment, the first substrate 10 can include a plurality of gate lines 151, a plurality of data lines 152, and a plurality of pixel electrodes 153. The gate lines 151 and the data lines 152 intersect with each other to define a plurality of pixels areas. In at least one embodiment, the gate lines 151 are arranged in parallel, and the data lines 152 are arrange in parallel as well as the gate lines 151. The gate lines 151 extend along a first direction while the data lines 152 extend along a second direction perpendicular with the first direction. Thus, the pixel area is rectangular. Each pixel area has a pixel electrode 153 and a TFT 100 located therein. The pixel electrode 153 is electrically coupled to the TFT 100. The pixel electrode 13 can be made of transparent materials, such as indium tin oxide (ITO).

As illustrated in FIG. 3, the TFT 100 can include a base 101, a gate 102, a first insulation layer 103, a channel layer 104, a source 105, a drain 106, a second insulation layer 107, and a flat layer 108. The gate 102 is located on the base 101. The first insulation layer 103 is located on and covers the base 101 and the gate 102. The channel layer 104 is located on the first insulation layer 103 and corresponds to the gate 102. Thus, the channel layer 104 is isolated and separated from the gate 102 by the first insulation layer 103. The gate 102 is electrically coupled to a corresponding gate line 151, the source 105 is electronically coupled to a corresponding data line 152, and the drain 106 is electrically coupled to a corresponding pixel electrode 153.

It is understood that, in other embodiments, the flat layer 108 can not be a part of the TFT 100, but rather, the flat layer 108 is mounted on the first substrate 10.

The source 105 and the drain 106 are respectively located at opposite sides of the channel layer 104 and coupled with the channel layer 104. The second insulation layer 107 is located at a surface of the channel layer 104 adjacent to the source 105 and drain 106 to separate the source 105 and the drain 106 from each other. The second insulation layer 107 can be made of transparent organic materials with light sensitivity performance. The second insulation layer 107 is configured to prevent the channel layer 104 from being damaged in the etching process for making the source 105 and the drain 106. A thickness of the second insulation layer 107 is about one micrometer. The channel layer 104 can be made of metal oxides, such as indium gallium zinc oxide (IGZO), indium zinc oxide (IZO), gallium zinc oxide (GZO), zinc tin oxide (ZTO), or zinc oxide (ZnO), or other like materials. The base 101 can be made of rigid and transparent inorganic materials, such as glass, quartz, or other like materials. In other embodiments, the base 101 can also be made of flexible organic materials, such as plastics, rubbers, polyesters, or other like materials.

In at least one embodiment, the pixel electrode 153 can be formed on the second insulation layer 107. The second insulation layer 107 can define at least one through hole 161 to allow the pixel electrode 153 to pass therethrough and to couple with the drain 106. The flat layer 108 can be formed on a surface of the second insulation layer 107 away from the base 101.

Generally, in order to increase the light transmittance of the flat layer 108, a photo bleaching process employing ultraviolet (UV) light may be applied to the flat layer 108. However, the channel layer 104 may suffer from the UV light. In the illustrated embodiment, the flat layer 108 includes a first region 108a corresponding to the channel layer 104 and a second region 108b beside and surrounding the first region 108a. The first region 108a and the second region 108b have different light transmittances. For example, the first region 108a can be translucent and become transparent under irradiation of ultraviolet (UV) light. The second region 108b can be transparent. Thus, the light transmittance of the first region 108a is less than the transmittance of the second region 108b. In this embodiment, the materials of the flat layer 108 can be organic materials such as polycarbonate (PC) and benzocyclobutene (BCB).

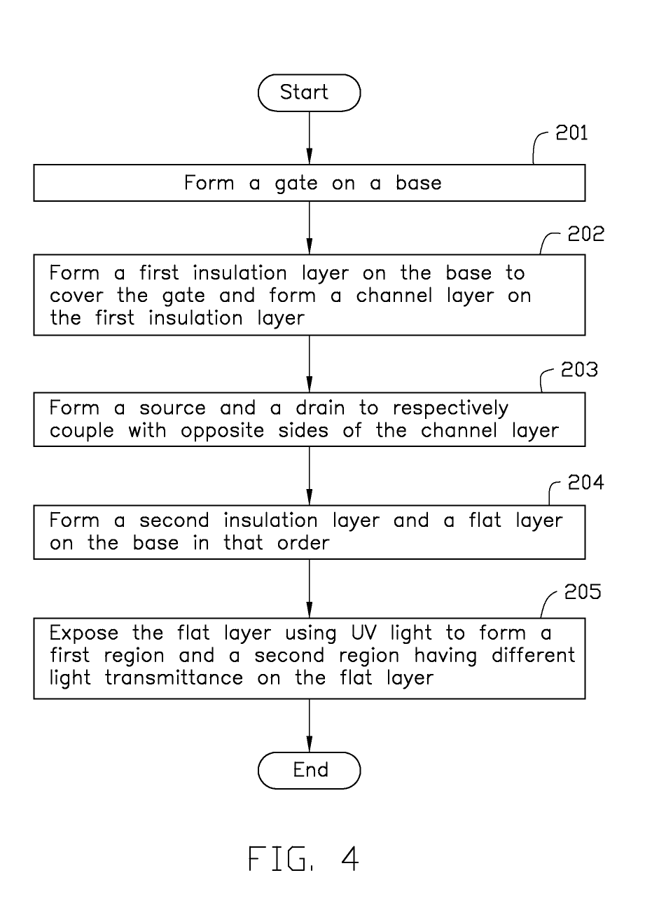

FIG. 4 illustrates a flowchart of method for manufacturing a TFT 100 of FIG. 3. The method is provided by way of example, as there are a variety of ways to carry out the method. Each block shown in FIG. 4 represents one or more processes, methods, or subroutines which are carried out in the example method. Furthermore, the order of blocks is illustrative only and the order of the blocks can change. Additional blocks can be added or fewer blocks may be utilized without departing from the scope of this disclosure. The example method can begin at block 201.

At block 201, a gate 102 is formed on a base 101.

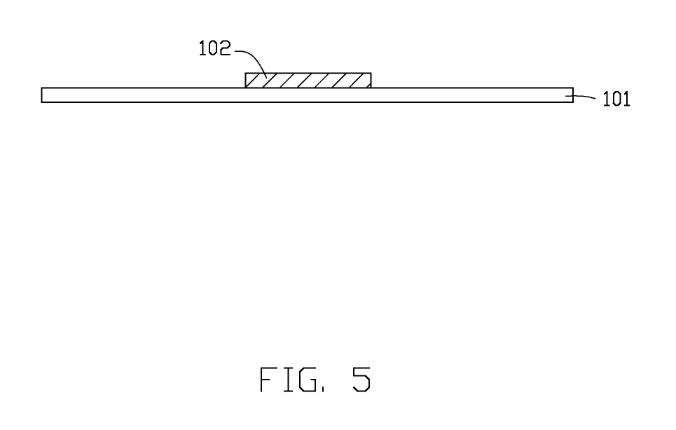

In at least one embodiment, a first conductive material layer is coated on the base 101 and is patterned to form the gate 102 on the base 101 as shown in FIG. 5. The first conductive material layer can be patterned using a photo etching process (PEP). The first conductive material layer can use metal materials, metal alloy materials, or metal oxide materials. The base 101 can be a transparent substrate such as a glass substrate, a quartz substrate, a flexible substrate. In other embodiments, the base 101 can be a non-transparent substrate or a translucent substrate. In at least one embodiment, the gate 102 can be formed in a same PEP process with the gate lines 151.

At block 202, a first insulation layer 103 is formed on the base 101 to cover the gate 102 and a channel layer 104 is formed on the first insulation layer 103.

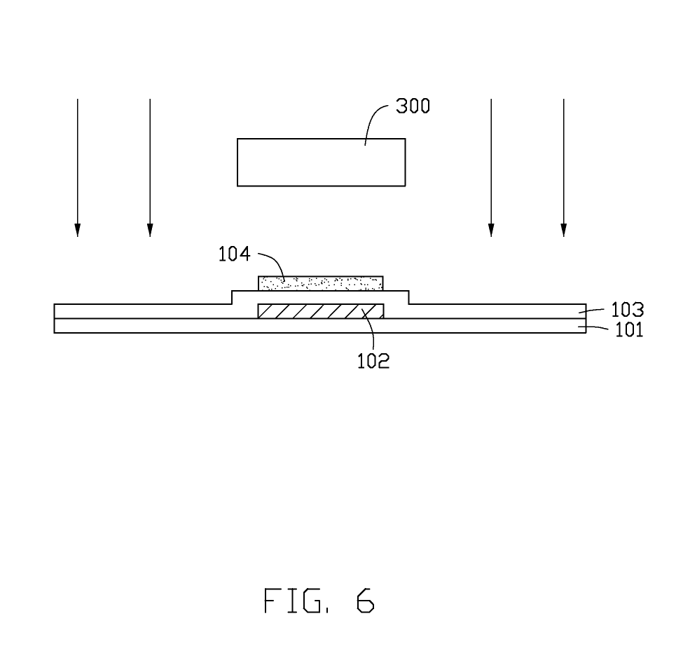

In at least one embodiment, as shown in FIG. 6, a layer of insulation materials is coated on the gate 102 and the base 101 to form the first insulation layer 103. The first insulation layer 103 can be made of inorganic transparent materials such as silicon nitride (SiNx) and silicon oxide (SiOx). The method for forming the gate insulation layer 103 can be a plasma chemical vapor deposition (PCVD) method. When the first insulation layer 103 is formed on the base 101, a layer of semiconductive materials such as IGZO, ZTO, and ZnO is coated on the first insulation layer 103. Then, the layer of semiconductive materials is patterned in a photo etching process using a photomask 300 to form the channel layer 104 corresponding to the gate 102.

At block 203, a source 105 and a drain 106 are respectively formed to couple with opposite sides of the channel layer 104.

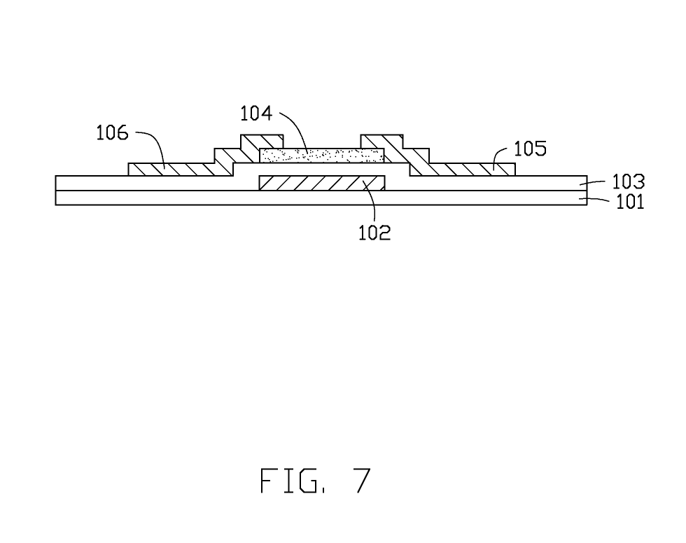

In at least one embodiment, a second conductive material layer can be coated to cover the first insulation layer 103 and the channel layer 104. Then, the second conductive material layer can be patterned using a photo etching process to form the source 105 and the drain 106 as shown in FIG. 7. The second conductive material layer can using the same materials with the first conductive material layer. In this embodiment, the source 105 and the drain 106 are respectively located at opposite sides of the channel layer 104 and are respectively contacted with the first insulation layer 103.

At block 204, a second insulation layer 107 and a flat layer 108 are respectively formed on the base 101 in that order.

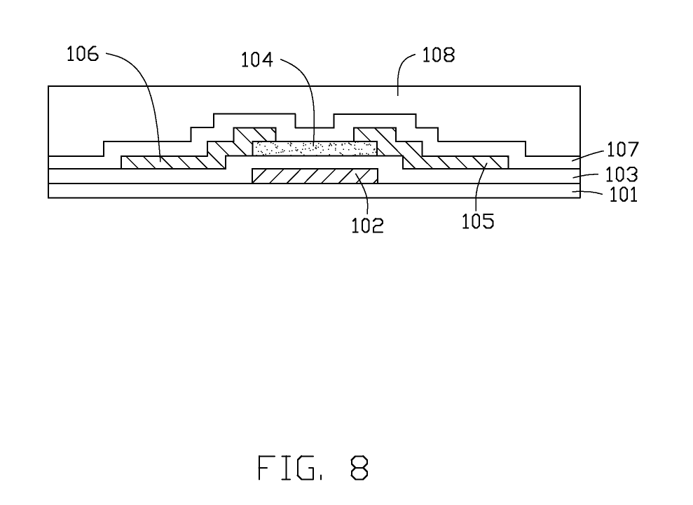

In at least one embodiment, as shown in FIG. 8, the second insulation layer 107 is first formed on the base 101 to cover the first insulation layer 103, the channel layer 104, the source 105, and the drain 106. Then, a layer of organic materials such as PC and BCB is formed on the second insulation layer 107 to form the flat layer 108. In the illustrated embodiment, the organic materials of the flat layer 108 are translucent which can become transparent under irradiation of UV light.

At bock 205, the flat layer 108 is exposed by UV light to form a first region 108a and a second region 108b having different light transmittance on the flat layer 108.

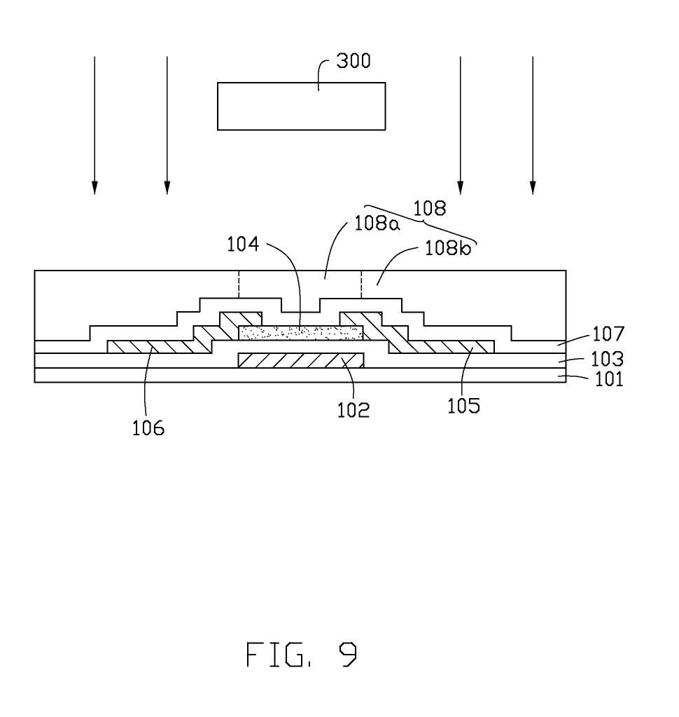

Referring to FIG. 9, in at least one embodiment, a photomask 300 above the flat layer 108 can be used to expose the flat layer 108 from a side of the flat layer 108 away from the base 101. The photomask 300 is located corresponding to the channel layer 104 to prevent the channel layer 104 from being exposed by the UV light, thereby avoiding the channel layer 104 to suffer from the UV light. Therefore, the second region 108b corresponding to the photomask 300 would not be exposed by the UV light and keep its original state. The first region 108a exposed by the UV light gradually becomes transparent and the light transmittance of the first region 108a is thus increased.

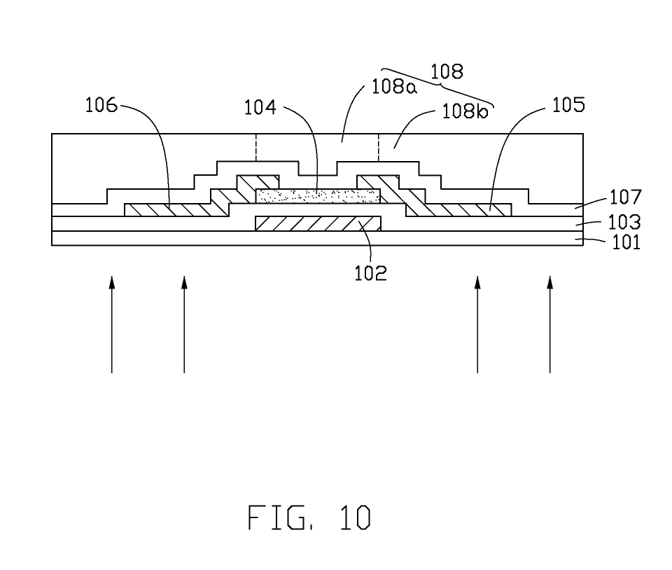

Referring to FIG. 10, in other embodiment, the flat layer 108 can also be exposed by the UV light from a side of the base 101 away from the flat layer 108 without using the photomask 300. Since the channel layer 104 is shielded by the gate 102, the channel layer 104 would not be exposed by the UV light and can not suffer from the UV light. Accordingly, a portion of the flat layer 108 corresponding to the channel layer 104 and the gate 102 would not be exposed by the UV light, therefore forming the first region 108a of the flat layer 108. The other portion of the flat layer 108 exposed by the UV light forms the second region 108b of the flat layer 108.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

1. A method for manufacturing a thin film transistor comprising:
forming a gate on a base;
forming a first insulation layer on the base to cover the gate;
forming a channel layer on the first insulation layer corresponding to the gate;
forming a source and a drain respectively coupled with opposite sides of the channel layer;
forming second insulation layer on the base to cover the first insulation layer, the channel layer, the source, and the drain; and
forming a flat layer having a first region and a second region on the second insulation layer, wherein the first region and the second region respectively have different light transmittance.

2. The method according to claim 1, wherein forming a flat layer having a first region and a second region on the second insulation comprises:
forming a layer of organic materials on the second insulation layer; and
exposing the organic materials by ultraviolet light using a photomask from a side of the flat layer away from the base to form the flat layer having the first region and the second region.

3. The method according to claim 2, wherein the photomask is located corresponding to prevent the channel layer from being exposed by the UV light.

4. The method according to claim 3, wherein the first region is corresponding to the channel layer and surrounded by the second region, and the light transmittance of the first region is less than the light transmittance of second region.

5. The method according to claim 2, wherein the organic materials are translucent capable of becoming transparent under irradiation of the ultraviolet light.

6. The method according to claim 1, wherein forming a flat layer having a first region and a second region on the second insulation comprises:
forming a layer of organic materials on the second insulation layer; and
exposing the organic materials by ultraviolet light from a side of base away from the flat layer to form the flat layer having the first region and the second.

7. The method according to claim 6, wherein the first region is corresponding to the gate and surrounded by the second region, and the light transmittance of the first region is less than the light transmittance of second region.

8. The method according to claim 6, wherein the organic materials are translucent capable of becoming transparent under irradiation of the ultraviolet light.

9. The method according to claim 6, wherein the base is made of transparent materials.

10. The method according to claim 1, wherein the first region is translucent and the second region is transparent.

11. A thin film transistor (TFT) comprising:
a gate formed on a base;
a first insulation layer covering the gate and the base;
a channel layer formed on the first insulation layer corresponding to the gate;
a source and a drain respectively coupled at opposite sides of the channel layer;
a second insulation layer covering the first insulation layer, the channel layer, the source and the drain; and
a flat layer having a first region and a second region, wherein the first region and the second region respectively have different light transmittance.

12. The TFT according to claim 11, wherein the first region is corresponding to the channel layer and surrounded by the second region, and the light transmittance of the first region is less than the light transmittance of second region.

13. The TFT according to claim 11, wherein the flat layer is made of translucent organic materials capable of becoming transparent under irradiation of ultraviolet light.

14. The TFT according to claim 13, wherein the first region is translucent and the second region is transparent.

15. An array substrate comprising:
a thin film transistor (TFT) having a channel layer; and
a flat layer covering the TFT and comprising a first region and a second region, wherein the first region and the second region respectively have different light transmittance.

16. The array substrate according to claim 15, wherein the first region is corresponding to the channel layer and surrounded by the second region, and the light transmittance of the first region is less than the light transmittance of second region.

17. The array substrate according to claim 15, wherein the flat layer is made of translucent organic materials capable of becoming transparent under irradiation of ultraviolet light.

18. The array substrate according to claim 17, wherein the first region is translucent and the second region is transparent.
